(19) United States
(12) Patent Application Publication
(10) Pub. No.: US 2014/0353597 A1
(43) Pub. Date: Dec. 4, 2014

(54) ORGANIC LIGHT EMITTING DISPLAY DEVICE AND MANUFACTURING METHOD THEREOF

(71) Applicant: Samsung Display Co., Ltd., Yongin-city (KR)

(72) Inventor: Ki-Wan Ahn, Yongin-city (KR)

(73) Assignee: Samsung Display Co., Ltd., Yongin-city (KR)

(21) Appl. No.: 14/026,696

(22) Filed: Sep. 13, 2013

(30) Foreign Application Priority Data
May 30, 2013 (KR) 10-2013-0061614

(51) Int. Cl. H01L 27/32; H01L 51/56

(52) U.S. Cl. CPC H01L 27/322; H01L 51/56
USPC 257/40; 438/34

(57) ABSTRACT

In an aspect, an organic light emitting display device including a substrate, a first electrode on the substrate, a pixel defining layer defining pixel areas disposed on the substrate, a plurality of pixels disposed at the pixel area, wherein one of the pixels comprises a first electrode, an auxiliary electrode layer only disposed on an upper surface of the first electrode, an emission layer on the auxiliary electrode layer, and a second electrode on the emission layer is provided.

### INCORPORATION BY REFERENCE TO RELATED APPLICATIONS

Any and all priority claims identified in the Application Data Sheet, or any correction thereto, are hereby incorporated by reference under 37 CFR 1.57. For example, this application claims priority to and the benefit of Korean Patent Application No. 10-2013-0061614, filed on May 30, 2013, with the Korean Intellectual Property Office, the disclosure of which is incorporated herein in its entirety by reference.

### BACKGROUND

1. Field

This disclosure relates to a display device that forms a pixel defining layer in advance during a process of manufacturing an anode electrode with respect to a resonance structure of the anode electrode applied to a top emission type, and a manufacturing method thereof.

2. Description of the Related Technology

An organic light emitting display device is a self-emission display device which has an organic light emitting diode that emits light to display an image. Unlike a liquid crystal display, the organic light emitting display device generally does not require a separate light source. As such, it is possible to relatively reduce a thickness and weight thereof. In addition, the organic light emitting display device may exhibit characteristics such as low power consumption, high luminance, and a rapid response speed.

The organic light emitting display device may be classified into a bottom emission type emitting light in a direction of a substrate and a top emission type emitting light in the opposite direction of the substrate. When a top emission type organic light emitting display device is manufactured, in order to improve light extraction efficiency, a reflective electrode is formed in a lower part of an anode or a metal layer is inserted into the anode. However, the organic light emitting display device may have problems in that an accurate emission spectrum may not be produced according to colors due to emission properties in accordance with wavelengths, the wavelengths are split, or luminance and color coordinate vary depending on colors. In this regard, the light extraction efficiency may be required to be enhanced respectively for pixels such as red, green, and blue pixels. Typically, a resonance structure is applied, in which an optical length between a reflective electrode and a cathode electrode varies depending on wavelengths.

### SUMMARY

Some embodiments provide an organic light emitting display device with an improved resonance structure. For example, some embodiments of the present disclosure provide a manufacturing method of an organic light emitting display device that improves a method of forming an auxiliary electrode layer at an anode, and an organic light emitting display device manufactured by the manufacturing method.

Some embodiments provide a display device comprising: a substrate; a pixel defining layer defining pixel areas disposed on the substrate; a plurality of pixels disposed at the pixel area; wherein one of the pixels comprises a first electrode; an auxiliary electrode layer only disposed on an upper surface of the first electrode; an emission layer on the auxiliary electrodes; and a second electrode on the emission layer.

In some embodiments, the pixel defining layer covers at least one of an upper surface and a side surface of the auxiliary electrode layer.

In some embodiments, the pixel defining layer contacts with a portion of an upper surface of the first electrode

In some embodiments, the pixel includes at least one of a red pixel, a green pixel and a blue pixel.

In some embodiments, the auxiliary electrode is disposed at the green pixel.

In some embodiments, the auxiliary electrode is disposed at at least one of the green pixel and the blue pixel.

In some embodiments, the emission layer comprises at least one of red emission material, green emission material and blue emission material.

In some embodiments, the pixel further may comprise a color filter layer on the second electrode.

In some embodiments, the first electrode includes at least one metal layer and at least one transparent conducting oxide (TCO) layer.

Some embodiments provide a method of manufacturing a display device, comprising: forming a first electrode on a substrate; forming a pixel defining layer defining pixel areas; forming a auxiliary electrode layer only at an upper surface of the first electrode; forming an emission layer on the auxiliary electrode layer; and forming a second electrode on the emission layer.

In some embodiments, the forming of the pixel defining layer includes forming a first structure of the pixel defining layer using a material of the pixel defining layer, and performing a first heat treatment for the first structure of the pixel defining layer.

In some embodiments, a curing temperature of the material of the pixel defining layer is T_{A}(° C.), and a temperature of the first heat treatment ranges from T_{A}-50° C. to T_{A}° C.

In some embodiments, the temperature of the first heat treatment ranges from 130° C. to 180° C.

In some embodiments, the method further includes performing a second heat treatment for the pixel defining layer before the forming of the emission layer and after the forming of the auxiliary electrode layer.

In some embodiments, the performing of the second heat treatment, the pixel defining layer is located at a portion of an upper surface of the auxiliary electrode layer by reflow of the pixel defining layer.

In some embodiments, a temperature of the second heat treatment ranges from T_{A}° C. to T_{A}+30° C.

In some embodiments, the temperature of the second heat treatment ranges from 210° C. to 280° C.

In some embodiments, the forming of the auxiliary electrode layer includes light exposure and etching using a photoresist.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating an organic light emitting display device according to a first embodiment of the present disclosure.

FIG. 2 is a cross-sectional view illustrating an organic light emitting display device according to a second embodiment of the present disclosure.

FIGS. 3A to 3G are diagrams illustrating a manufacturing process of the organic light emitting display device according to embodiments of the present disclosure.

FIG. 4 is a cross-sectional view illustrating an organic light emitting display device according to a third embodiment of the present disclosure.

FIG. 5 is a diagram illustrating the organic light emitting display device illustrated in FIG. 1 in more detail.

### DETAILED DESCRIPTION

Hereinafter, embodiments of the present disclosure will be described in more detail with reference to the accompanying drawings. However, the scope of the present embodiments is not limited to the following examples and drawings. Embodiments to be described below and illustrated in the drawings may include various equivalences and modifications.

The terminology used in this specification is used in order to express embodiments of the present disclosure and may depend on the intention of users or operators or the custom in the art to which the present disclosure belongs. Accordingly, the terminology should be viewed in the context of the details described throughout this specification.

For reference, respective components and shapes thereof may be schematically drawn or exaggeratedly drawn in the accompanying drawings for ease of understanding. Like reference numerals designate like elements throughout the drawings.

Further, it will be understood that when a layer or an element is described as being “on” another layer or element, it may be directly disposed on another layer or element, or an intervening layer or element may also be present.

### First Embodiment

A first embodiment is based on the premise that an organic light emitting display device of the present disclosure is a top emission type display device. An anode is described as having a concept including a first electrode and an auxiliary electrode layer which will be described below.

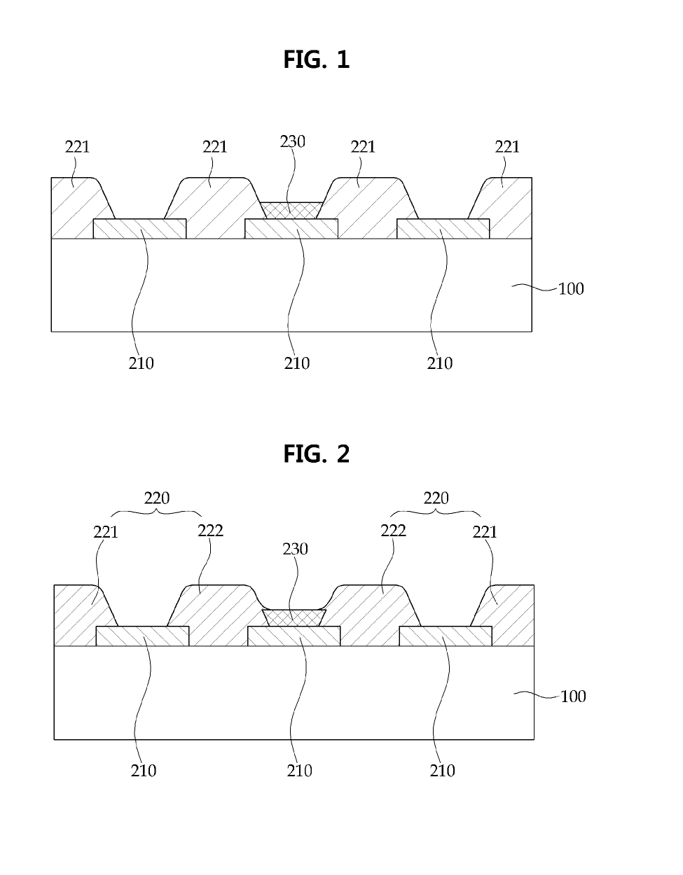

FIG. 1 is a cross-sectional view illustrating an organic light emitting display device according to the first embodiment of the present disclosure.

Referring to FIG. 1, the organic light emitting display device according to the first embodiment of the present disclosure includes a substrate 100, a first electrode 210, a pixel defining layer 220, and an auxiliary electrode layer 230.

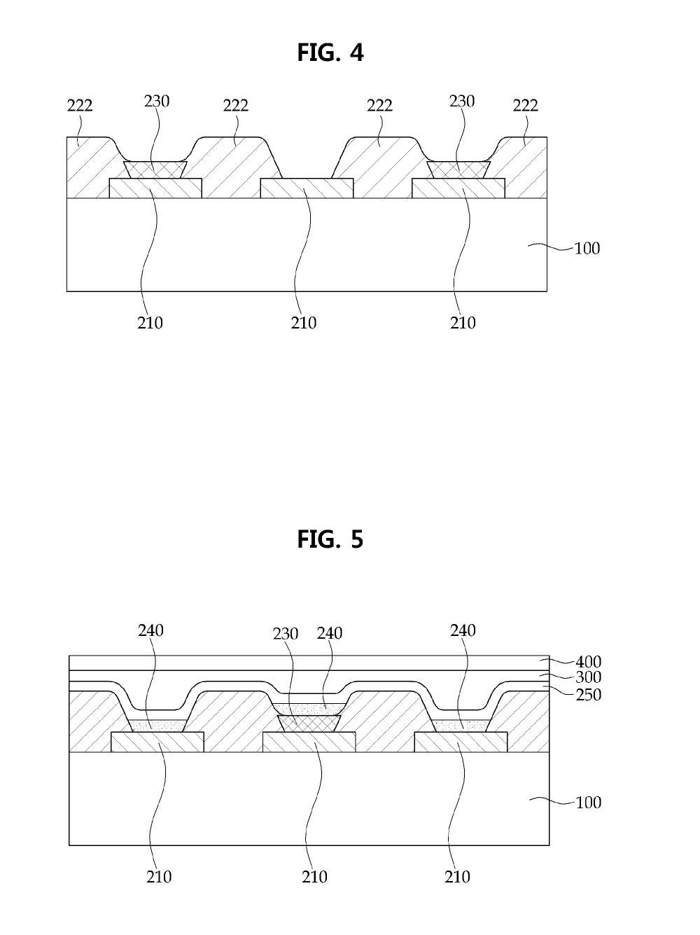

In view of FIG. 5 described below, the organic light emitting display device according to the first embodiment of the present disclosure includes a substrate 100, a pixel defining layer 220 defining pixel areas on the substrate, a plurality of pixels disposed at the pixel areas.

In some aspects, the substrate 100 may be formed of a variety of materials such as a glass substrate, a quartz substrate, and a transparent resin substrate, and may be formed by using a flexible material. In some aspects, the transparent resin substrate which may be used as the substrate 100 may contain a polyimide resin, an acrylic resin, a polyacrylate resin, a polycarbonate resin, a polyether resin, a polyethylene terephthalate resin, a sulfonic acid resin, and the like.

In the case where the organic light emitting display device is a bottom emission type display device, the substrate 100 needs to be formed of a light transmitting material, but since the organic light emitting display device of the present disclosure is a top emission type display device, the substrate 100 may not be necessarily formed of the light transmitting material.

In some aspects, one of the pixels comprises a first electrode 210, an auxiliary electrode layer 230 only disposed on an upper surface of the first electrode 210, an emission layer 240 on the auxillary electrode layer 230, and a second electrode 250 on the emission layer 240.

In some aspects, the pixel defining layer and the pixels are collectively called a display unit 200. In some aspects, the pixels may comprise at least one of red pixel, a green pixel and a blue pixel. In some aspects, the emission layer 240 may comprise at least one of red emission material, green emission material and blue emission material.

In some aspects, the first electrode 210 is formed on the substrate 100, and with respect to the top emission type structure, the first electrode 210 needs to provide a reflective layer so as to enhance light extraction efficiency, and thus may contain at least one metal layer and at least one transparent conducting oxide (TCO) layer. For example, the metal layer may contain at least one of gold (Au), silver (Ag), platinum (Pt), nickel (Ni), tungsten (W), chromium (Cr), molybdenum (Mo), iron (Fe), cobalt (Co), copper (Cu), palladium (Pd), titanium (Ti), and a combination thereof. The transparent conducting oxide layer may contain at least one of indium tin oxide (ITO) and indium zinc oxide (IZO). In some aspects, the metal layer acts as the reflective layer. In some aspects, the first electrode 210 may be formed by containing a material known in the art.

Referring to FIG. 1, the pixel defining layer 220 covers a side surface but not an upper surface of the auxiliary electrode layer 230. In some aspects, the pixel defining layer 220 may include a first structure 221 thereof to cover a side surface but not an upper surface of the auxiliary electrode layer 230.

Also, referring to FIG. 1, in the pixel having the auxiliary electrode layer 230, the pixel defining layer 220 contacts with a side surface and a portion of an upper surface of the first electrode 210.

In some aspects, as shown in FIG. 1, the first structure 221 of the pixel defining layer 220 is formed at the green pixel comprising the auxiliary electrode. Functions and effects of the first structure 221 of the pixel defining layer 220 will be described below together with a manufacturing method thereof. A material of the pixel defining layer 220 will be also described below together with the manufacturing method thereof.

In some aspects, the auxiliary electrode layer 230 is located at an upper surface of the first electrode 210, and side surfaces of the auxiliary electrode layer 230 are in contact with the pixel defining layer 220.

In some aspects, the auxiliary electrode layer 230 may be located at the green pixel area located in the center. Laminating the auxiliary electrode layer 230 only in the green-pixel area is merely an example, and the auxiliary electrode layer 230 may be formed to change its thickness according to a pixel in view of micro resonance and wavelength of each pixel.

In some aspects, the auxiliary electrode layer 230 may contain at least one of indium tin oxide (ITO) and indium zinc oxide (IZO) which are transparent conductive oxides. In some aspects, the auxiliary electrode layer 230 is an element to make a difference in thickness of the first electrode 210 and thus may be formed of the same material as a transparent conductive oxide inserted into the first electrode 210. In some aspects, the auxiliary electrode layer 230 may be formed by containing a material known in the art.

By laminating the auxiliary electrode layer 230 on the first electrode 210, an anode is formed to have different thicknesses according to each pixel area.

Referring to FIG. 5, the pixel may further comprise a capping layer 300 and an encapsulation layer 400 on the capping layer 300.

Although not shown in Figs, the embodiment of the disclosure may apply to a so-called white OLED device including an emission layer of the pixel having red emission material, green emission material and blue emission material.

In some aspects, the organic light emission display device may further include a color filter layer on the second electrode 250. In some aspects, the color filter layer may be formed as a red color filter corresponding to the red pixel, a green color filter corresponding to the green pixel and a blue color filter corresponding to the blue pixel. In some aspects, the type of the color filter layer may be formed corresponding to the emission color of the pixels.

### Second Embodiment

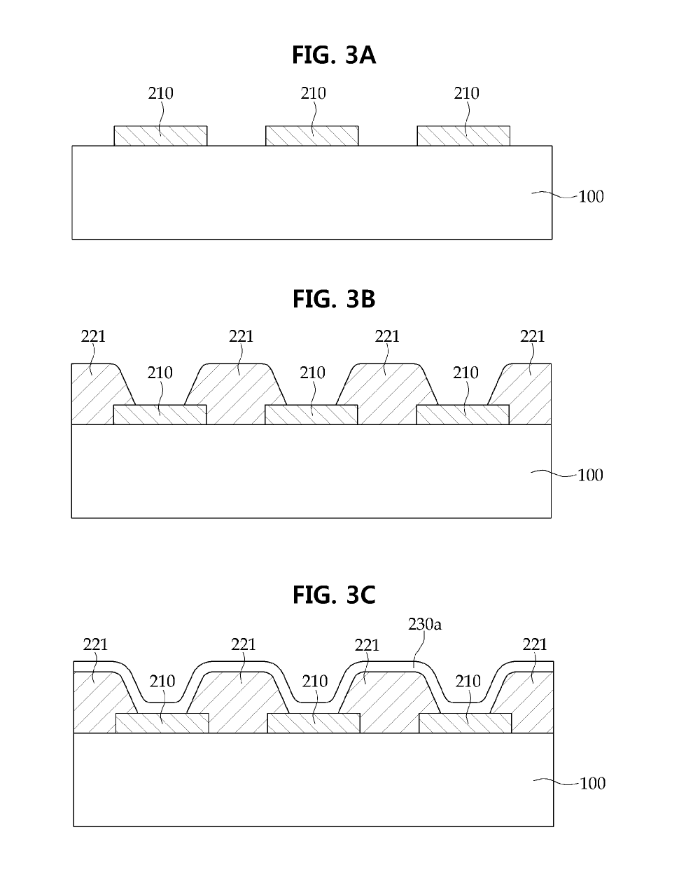

FIG. 2 is a cross-sectional view illustrating an organic light emitting display device according to a second embodiment of the present disclosure.

Hereinafter, the second embodiment of the present disclosure will be described with omitting the same element as the first embodiment of the present disclosure.

Referring to FIG. 2, the pixel defining layer 220 covers a side surface and an upper surface of an auxiliary electrode layer 230. In some aspects, the pixel defining layer 220 contacts with a side surface and a portion of an upper surface of a first electrode 210 in the pixel having the auxiliary electrode layer 230.

In the case where an edge of the auxiliary electrode layer 230 is exposed, current density is concentrated and thus a life span of organic light emitting display devices is reduced. For this reason, a portion of an upper surface of the auxiliary electrode layer 230 is covered by the pixel defining layer 220 by being in contact therewith.

As shown in FIG. 2, the pixel defining layer 220 may include a second structure 222 covering a side surface and a portion of an upper surface of the auxiliary electrode layer 230. In this case, the second structure 222 of the pixel defining layer 220 is formed by reflowing the pixel defining layer on the portion of the upper surface of the auxiliary electrode layer 230 under heat treatment and is located at an upper surface of the first electrode 210, and side surfaces of the auxiliary electrode layer 230 are in contact with the pixel defining layer 220.

As shown in FIG. 2, the first structure 222 of the pixel defining layer 220 is formed at the green pixel comprising the auxiliary electrode. Functions and effects of the second structure 222 of the pixel defining layer 220 will be described below together with a manufacturing method thereof. A material of the pixel defining layer 220 will be also described below together with the manufacturing method thereof.

### Method for Manufacturing

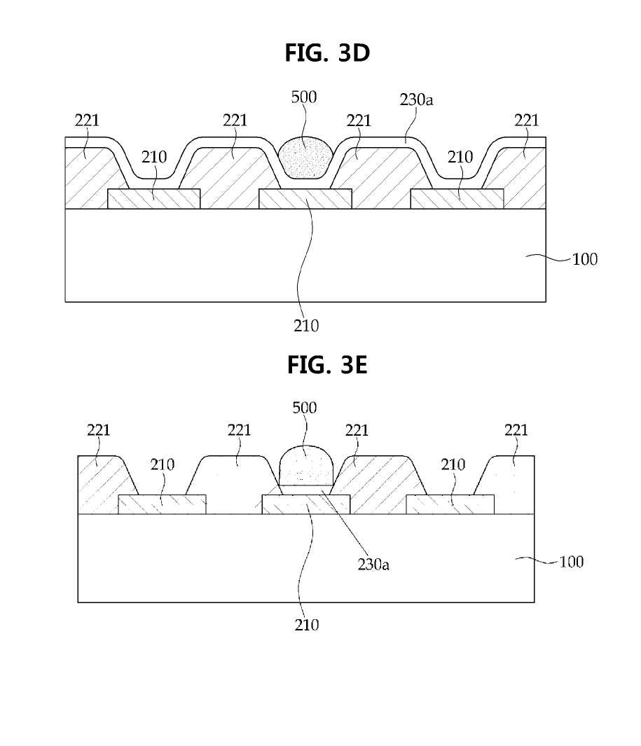

FIGS. 3A to 3G are diagrams illustrating a manufacturing process of the organic light emitting display device according to embodiments of the present disclosure.

Referring to FIG. 3, a first electrode 210 is first formed on a substrate 100. In some aspects, the first electrode 210 may be formed of ITO/Ag/ITO, ITO/Ag/IZO (Indium Zinc Oxide), ITO/Ag alloy/ITO, or the like, and Ag may play a role in reflecting light. In some aspects, the first electrodes 210 are sequentially laminated by vacuum deposition or sputtering, and thereafter may be etched and patterned at the same time by a first photolithography process. In some aspects, an etching solution may include nitric acid or acetic acid. As illustrated in FIG. 3A, three first electrodes 210 corresponding to red, green, and blue emission pixels may be formed from the left side of the substrate 100. The three first electrodes 210 are merely illustrated in line with three representative pixels for the convenience of description, and the number of the first electrode 210 may be determined as appropriate.

Referring to FIG. 3B, a pixel defining layer 220 defining pixel areas is formed on the substrate 100.

In some aspects, the forming of the pixel defining layer 220 includes forming a first structure 221 of the pixel defining layer using a material thereof and performing a first heat treatment for the first structure 221 of the pixel defining layer.

In some aspects, the first structure 221 of the pixel defining layer may be formed by laminating the pixel defining layer 220 by vacuum deposition or sputtering and thereafter by etching and patterning the pixel defining layer 220 by a photolithography process. For example, an opening is formed by etching the pixel defining layer 220 to expose a part of the first electrode 210. In some aspects of the manufacturing process, the first structure 221 of the pixel defining layer may be in a state of being soft due to viscosity, not being cured, and maintaining its shape.

In some aspects, the first heat treatment for the first structure 221 of the pixel defining layer may be performed before an auxiliary electrode layer-forming material 230a illustrated in FIG. 3C is laminated, but it may be performed simultaneously with carrying out processes of post-exposure bake (PEB) and hard bake (HB) of a photoresist pattern 500 for the convenience of a manufacturing process. Therefore, the first heat treatment will be described below in the process of forming the photoresist pattern 500 in detail.

In some aspects, the pixel defining layer 220 including the first structure 221 may be an organic material. In some aspects, the organic material may be any one of acrylic organic compounds and organic insulation materials such as polyamide, polyimide, and the like.

Referring to FIGS. 3C to 3F, an auxiliary electrode layer 230 is formed at an opening of the first electrode 210 by using a second photolithography process. First, the auxiliary electrode layer-forming material 230a (ex.: a-ITO (amorphous-ITO)) is laminated on the opening of the first electrode 210 and the first structure 221 of the pixel defining layer 220 (FIG. 3C).

Hereinafter, it will be described considering use of a-ITO as the auxiliary electrode layer-forming material 230a.

Thereafter, a photoresist (not shown in the drawings) is coated on the auxiliary electrode layer-forming material 230a. The auxiliary electrode layer-forming material 230a coated with the photoresist is exposed to light and developed through a photomask (not shown in the drawings) to form the photoresist pattern 500 above the first electrode 210 of the green emission area located in the center (FIG. 3D). Then, the auxiliary electrode layer-forming material 230a where the photoresist pattern 500 is not formed is etched using the photomask so that the photoresist pattern 500 may remain only (FIG. 3E). And then, the photoresist pattern 500 is stripped by using stripper or wet etching. As a result, the auxiliary electrode layer 230 is formed only on the first electrode 210 located in the green pixel (FIG. 3F). Thus, in the forming of the auxiliary electrode layer 230, the auxiliary electrode layer 230 is formed to fill an entire surface of the opening of the first electrode 210 so that side surfaces of the auxiliary electrode layer 230 may be formed to be in contact with the first structure 221 of the pixel defining layer. Next, an emission layer 240 is formed on the auxiliary electrode layer 230, and a second electrode 250 is formed on the emission layer 240.

In some aspects, as illustrated in FIG. 3E, since the auxiliary electrode layer-forming material 230a is first etched, and thereafter as illustrated in FIG. 3F, the photoresist pattern 500 is stripped, the first structure 221 of the pixel defining layer may be completely exposed to the etching solution required for the strip and may be etched along with the auxiliary electrode layer-forming material. Therefore, the first structure 221 of the pixel defining layer needs to be incompletely cured by performing the first heat treatment during the processes of post-exposure bake (PEB) and hard bake (HB) of the photoresist pattern 500. In the case where the first structure 221 of the pixel defining layer is incompletely cured, it is not damaged during the process of stripping the photoresist pattern 500.

For the above reason, it is necessary to perform the heat treatment for the first structure 221 of the pixel defining layer, and thus the heat treatment process will be described below. Hereinafter, in order to clarify meanings, a heat treatment to cure incompletely the first structure 221 of the pixel defining layer is named a first heat treatment, and another heat treatment to form the second structure 222 of the pixel defining layer by curing the first structure 221 of the pixel defining layer is named a second heat treatment.

First, the incomplete cure is in a state when the pixel defining layer 220 is not cured, and may be in a thick liquid state that has higher viscosity than water, in which a portion of the pixel defining layer 220 does not flow down. Since the first structure 221 of the pixel defining layer is incompletely cured, when the second heat treatment is performed for the first structure 221 of the pixel defining layer, a portion of the first structure 221 of the pixel defining layer may flow down. In some aspects, a curing temperature of a material of the pixel defining layer 220 is T_{A}(° C.), and the curing temperature refers to a temperature at which the pixel defining layer 220 may be cured.

As described above, the first heat treatment for the first structure 221 of the pixel defining layer may be performed simultaneously with the process of curing the photoresist pattern 500. In this case, the first heat treatment for the first structure 221 of the pixel defining layer may be performed at a temperature ranging from T_{A}-50° C. to T_{A}° C., and specifically the temperature of the first heat treatment may range from 130° C. to 180° C. For example, the temperature of the first heat treatment may be 150° C., the photoresist pattern 500 may be cured at the temperature of 150° C., the first structure 221 of the pixel defining layer may be incompletely cured at the temperature of 150° C., and the auxiliary electrode layer-forming material 230a may not be cured at a level of p-ITO(Poly-crystal ITO) at the temperature of 150° C. The reason why the first heat treatment for the first structure 221 of the pixel defining layer is performed at the temperature as above is as follows. In some aspects, the reason for being the at temperature at which the photoresist pattern 500 is cured is because the photoresist pattern 500 needs to be cured to prevent being etched in the etching of the auxiliary electrode layer-forming material 230a during the photolithography process. In some aspects, the reason for being at the temperature at which the pixel defining layer 220 is incompletely cured is because the first structure 221 of the pixel defining layer needs to be incompletely cured to prevent being removed in the process of stripping the photoresist pattern 500. In some aspects, the reason for being at the temperature at which the auxiliary electrode layer-forming material 230a is not cured at a level of p-ITO is because the auxiliary electrode layer-forming material 230a needs to be removed in the etching during the photolithography process.

Therefore, the first heat treatment for the first structure of the pixel defining layer needs to be performed at the temperature meeting all of the above three requirements so that the process of the present disclosure may be performed.

In some aspects, the first heat treatment process for the incomplete cure of the first structure 221 of the pixel defining layer may be performed in the manufacturing step illustrated in FIG. 3B. In some aspects, when the pixel defining layer 220 is first formed, the first heat treatment may be performed to incompletely cure the first structure 221 of the pixel defining layer.

Referring to FIG. 3G, a second heat treatment may be performed to the pixel defining layer 220 before the forming of the emission layer 240 and after the forming of the auxiliary electrode layer 230.

In some aspects of the performing of the second heat treatment, the pixel defining layer 220 is reflowed to be located at an end portion of an upper surface of the auxiliary electrode layer 230. In some aspects, the pixel defining layer 220 disposed at the end portion of an upper surface of the auxiliary electrode layer 230 may include a second structure 222.

As described above, the second structure 222 of the pixel defining layer is to prevent a decline in life expectancy of a device, which is caused by current density concentrated at an edge of the auxiliary electrode layer 230.

In some aspects, as illustrated in FIG. 3G, a degree of flow of the pixel defining layer 220 needs to be controlled so that that the second structure 222 of the pixel defining layer may cover only part of an end portion of the upper auxiliary electrode layer 230, and thus the pixel defining layer 220 may be formed by mixing two or more materials. In some aspects, the pixel defining layer 220 consisting of the two or more materials may have characteristics that can easily reflow at different temperatures. Therefore, the pixel defining layer 220 may be configured in order that only a part of the pixel defining layer 220, which is in contact with the auxiliary electrode layer 230, may flow down at the same temperature.

In some aspects, the second heat treatment to form the second structure 222 of the pixel defining layer may be performed at a temperature ranging from T_{A}° C. to T_{A}+30° C., and specifically the temperature of the second heat treatment may range from 210° C. to 280° C. For example, when the temperature is 230° C., the temperature of 230° C. may be a temperature at which the pixel defining layer 220 may be cured and at which the auxiliary electrode layer 230 may be cured at a level of p-ITO(Poly-ITO). In some aspects, the reason for being the temperature at which the pixel defining layer 220 is cured is because the pixel defining layer 220 is formed onto the auxiliary electrode layer 230 and an anode is formed as a whole, and thus the pixel defining layer 220 is fixed and only a portion of the pixel defining layer 220 flows down, thereby covering part of an end portion of the upper auxiliary electrode layer 230. In some aspects, the reason for being the temperature at which the auxiliary electrode layer 230 is cured at a level of p-ITO(Poly-ITO) is because a differential structure of the whole anode is formed, and thus the auxiliary electrode layer 230 needs to be cured to be maintained.

By performing the second heat treatment to the second structure 222 of the pixel defining layer, the second structure 222 of the pixel defining layer may cover the side surface and the portion of the upper surface of the auxiliary electrode layer 230, thereby prolonging life span of the organic light emitting display device.

When the processes illustrated in FIGS. 3A to 3G are taken together in simple and sequential manners, the manufacturing method of the organic light emitting display device includes forming the first electrode 210 on the substrate 100; forming the first structure 221 of the pixel defining layer using a material of the pixel defining layer; forming the photoresist pattern 500 in a green pixel and performing the first heat treatment to the first structure 221 of the pixel defining layer; locating the auxiliary electrode layer 230 only on the upper surface of the first electrode 210 of the green pixel; forming a second structure 222 of the pixel defining layer by performing the second heat treatment; forming the emission layer 240 on the auxiliary electrode layer 230; and forming the second electrode 250 on the emission layer 240.

The manufacturing method of the organic light emitting display device of the present disclosure may reduce one photolithography process, compared with a conventional manufacturing process for resonance structure. For example, a conventional manufacturing process for resonance structure which will be described below to help facilitate understanding of the differences of the manufacturing processes.

In a conventional manufacturing process for resonance structure, three photolithography processes are generally required to apply the resonance structure. ITO, AG, and ITO are sequentially laminated on a substrate, a first photoresist pattern is formed, and anodes including a metal layer are formed according to each pixel in the same manner through an etching process (a first photolithography process). Among the anodes formed in the first photolithography process, a second photoresist pattern is formed only at an anode which may not make a change in thickness (a second photolithography process). The second photoresist pattern is to prevent side penetration of a metal layer included in the anode which may not make a change in thickness. Thereafter, transparent conducting oxides (ex.: a-ITO) are laminated on all anodes, and then a third photoresist pattern is formed on an anode which may make a change in thickness (a third photolithography process). Lastly, the second photoresist pattern and a-ITO are removed by light exposure and etching, and the third photoresist pattern is also removed, and then the resonance structure is formed, wherein a-ITO is further laminated only on the anode at which the third photoresist pattern is formed.

A conventional manufacturing process for the resonance structure has problems of increasing manufacturing costs and complicating a manufacturing process since the three photolithography processes are required due to a differential application of thickness of the anodes. Further, when the second photoresist pattern is formed, in order to obtain an area to cap the anodes with the photoresist pattern, a distance between the anodes increases, and this leads in loss of an aperture ratio.

In the organic light emitting display device of the present disclosure, the pixel defining layer 220 is first formed, and thus problems with a conventional manufacturing process may solved. For example, the pixel defining layer 220 protects a metal layer inside an anode earlier formed, and the photoresist pattern of a conventional manufacturing process is not necessary, and thus manufacturing costs may be reduced, process efficiency may be improved, and the loss of an aperture ratio is prevented.

### Third Embodiment

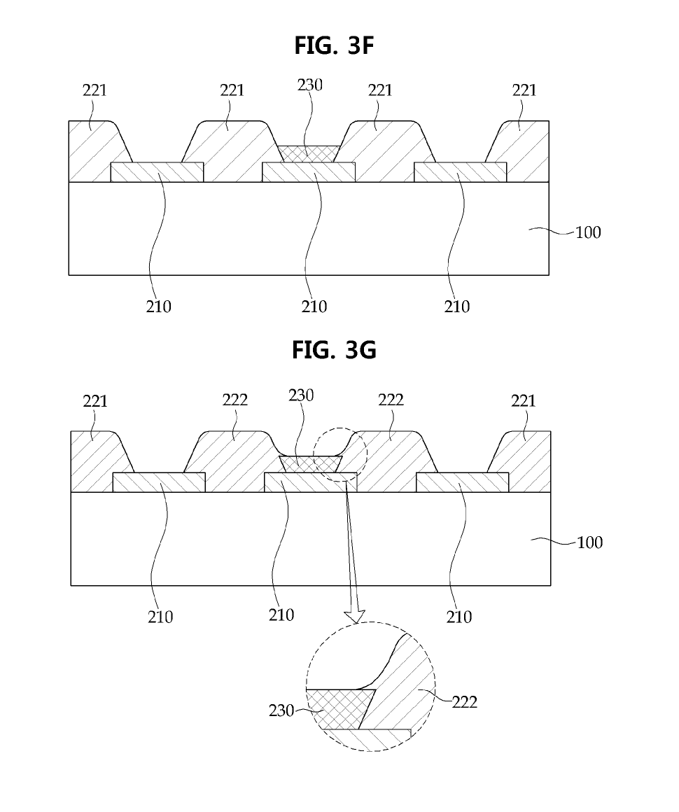

FIG. 4 is a cross-sectional view illustrating an organic light emitting display device according to a third embodiment of the present disclosure.

Referring to FIG. 4, the auxiliary electrode layer 230 may be formed on a first electrode 210 corresponding to the red pixel area and the blue pixel area except for a first electrode 210 corresponding to the green pixel area in the center.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A display device, comprising:
a substrate;
a pixel defining layer defining pixel areas disposed on the substrate;
a plurality of pixels disposed at the pixel area;
wherein one of the pixels comprises a first electrode;
an auxiliary electrode layer only disposed on an upper surface of the first electrode;
an emission layer on the auxiliary electrodes; and
a second electrode on the emission layer.

2. The display device of claim 1, wherein the pixel defining layer covers at least one of an upper surface and a side surface of the auxiliary electrode layer.

3. The display device of claim 2, wherein the pixel defining layer contacts with a portion of an upper surface of the first electrode.

4. The display device of claim 1, wherein the pixel includes at least one of a red pixel, a green pixel and a blue pixel.

5. The display device of claim 4, wherein the auxiliary electrode is disposed at the green pixel.

6. The display device of claim 4, wherein the auxiliary electrode is disposed at a location corresponding to at least one of the red pixel and the blue pixel.

7. The display device of claim 4, wherein the emission layer comprises at least one of red emission material, green emission material and blue emission material.

8. The display device of claim 7, wherein the pixel further comprises a color filter layer on the second electrode.

9. The display device of claim 1, wherein the first electrode includes at least one metal layer and at least one transparent conducting oxide (TCO) layer.

10. A method of manufacturing a display device, comprising:
forming a first electrode on a substrate;
forming a pixel defining layer defining pixel areas;
forming a auxiliary electrode layer only at an upper surface of the first electrode;
forming an emission layer on the auxiliary electrode layer; and
forming a second electrode on the emission layer.

11. The method of claim 10, wherein the forming of the pixel defining layer includes forming a first structure of the pixel defining layer using a material of the pixel defining layer, and performing a first heat treatment for the first structure of the pixel defining layer.

12. The method of claim 11, wherein a curing temperature of the material of the pixel defining layer is T_{A}(° C.), and a temperature of the first heat treatment ranges from T_{A}-50° C. to T_{A}° C.

13. The method of claim 11, wherein a temperature of the first heat treatment ranges from 130° C. to 180° C.

14. The method of claim 10, further including performing a second heat treatment for the pixel defining layer before the forming of the emission layer and after the forming of the auxiliary electrode layer.

15. The method of claim 14, wherein in the performing of the second heat treatment, the pixel defining layer is located at a portion of an upper surface of the auxiliary electrode layer by reflow of the pixel defining layer.

16. The method of claim 14, wherein a curing temperature of the pixel defining layer is T_{A}(° C.), and a temperature of the second heat treatment ranges from T_{A}° C. to T_{A}+30° C.

17. The method of claim 14, wherein a temperature of the second heat treatment ranges from 210° C. to 280° C.

18. The method of claim 10, wherein the forming of the auxiliary electrode layer includes light exposure and etching using a photoresist.
